(19) United States
(12) Patent Application Publication
(10) Pub. No.: US 2026/0104649 A1
(43) Pub. Date: Apr. 16, 2026

(54) OPTICAL PROXIMITY CORRECTION (OPC) METHOD BASED ON DEEP LEARNING

(71) Applicant: Samsung Electronics Co., Ltd., Suwon-si (KR)

(72) Inventors: Minho Kim, Suwon-si (KR); Kyoungyoon Park, Suwon-si (KR); Jihyeon Woo, Suwon-si (KR); Useong Kim, Suwon-si (KR)

(21) Appl. No.: 19/330,265

(22) Filed: Sep. 16, 2025

(30) Foreign Application Priority Data
Oct. 10, 2024 (KR) 10-2024-0137689

(51) Int. Cl. G03F 7/00

(52) U.S. Cl. CPC G03F 7/70441; G03F 7/705; G03F 7/706839

(57) ABSTRACT

A method of manufacturing includes receiving a design layout of a target pattern, generating an optical proximity correction (OPC) model the design layout, obtaining an optical proximity corrected (OPCed) design layout by a simulation based on the OPC model, and forming at least one of a mask and a semiconductor device using the OPCed design layout, wherein the generating of the OPC model includes obtaining a vectorized first kernel by vectorizing a first kernel, preparing a first input image by using the design layout of the target pattern, obtaining a vectorized first input image by vectorizing the first input image, obtaining a first rotation image by rotating the vectorized first input image in a first direction, extracting a second kernel by calculating a dot product of the vectorized first kernel and the first rotation image, obtaining a second rotation image by symmetrizing the first rotation image, and extracting a fourth kernel by calculating a dot product of the vectorized first kernel and the second rotation image. The simulation is performed by using the second kernel.

### CROSS-REFERENCE TO RELATED APPLICATION

This application is based on and claims priority under 35 U.S.C. § 119 to Korean Patent Application No. 10-2024-0137689, filed on Oct. 10, 2024, in the Korean Intellectual Property Office, the disclosure of which is incorporated by reference herein in its entirety.

### BACKGROUND

The inventive concept relates to an optical proximity correction (OPC) method and a method of manufacturing at least one of a mask and a semiconductor device using the OPC method.

In a semiconductor manufacturing process, photolithography using a mask may be performed to form a pattern on a semiconductor substrate such as a wafer. A mask may be a patterning tool (e.g., pattern transfer article), in which a pattern (to be transferred to the wafer during the photolithography process) including an opaque material is formed on a transparent base material. Briefly, in a mask manufacturing process, a desired circuit is planned, the layout of the desired circuit is designed, and design data obtained through OPC is delivered as mask tape-out (MTO) design data. Thereafter, mask data preparation (MDP) is performed based on the MTO design data and an exposure process may be performed on a mask substrate.

### SUMMARY

The inventive concept provides an optical proximity correction (OPC) method with improved simulation performance. In addition, the invention provides a method for manufacturing at least one of a mask and a semiconductor device using the OPC method.

However, aspects of the inventive concept are not limited to those mentioned above. Above and other aspects of the inventive concept that have not been mentioned will be clearly understood by one of skill in the art from the description below.

According to an aspect of the inventive concept, there is provided a method of manufacturing. The method includes receiving a design layout of a target pattern, generating an OPC model, obtaining an optical proximity corrected (OPCed) design layout by a simulation using the OPC model, and forming at least one of a mask and a semiconductor device using the OPCed design layout, wherein the generating of the OPC model includes obtaining a vectorized first kernel by vectorizing a first kernel, preparing a first input image by using the design layout of the target pattern, obtaining a vectorized first input image by vectorizing the first input image, obtaining a first rotation image by rotating the vectorized first input image in a first direction, and extracting a second kernel by calculating a dot product of the vectorized first kernel and the first rotation image. The simulation is performed by using the second kernel.

According to another aspect of the inventive concept, there is provided a method of manufacturing. The method includes receiving a design layout of a target pattern, generating a first OPC model reflecting an optical phenomenon in an exposure process, generating a second OPC model reflecting an influence of a side surface of a photoresist (PR) in the exposure process, obtaining an OPCed design layout by a simulation using an OPC model including the first OPC model and the second OPC model, and forming at least one of a mask and a semiconductor device using the OPCed design layout, wherein the generating of the second OPC model includes preparing a first input image and a second input image by using the design layout of the target pattern, obtaining a vectorized first kernel by vectorizing a first kernel, obtaining a vectorized first input image by vectorizing the first input image, obtaining a rotation image by rotating the vectorized first input image, and extracting a second kernel by calculating a dot product of the vectorized first kernel and the rotation image. The obtaining of the OPCed design layout includes extracting an output image by convoluting the second kernel and the second input image.

According to another aspect of the inventive concept, there is provided a method of manufacturing. The method includes receiving a design layout of a target pattern, generating an OPC model, obtaining an OPCed design layout by a simulation using the OPC model, and forming at least one of a mask and a semiconductor device using the OPCed design layout, wherein the generating of the OPC model includes preparing a first input image by using the design layout of the target pattern, obtaining a vectorized first kernel by vectorizing a first kernel, obtaining a vectorized first input image by vectorizing the first input image, obtaining a first rotation image by rotating the vectorized first input image, and obtaining a second rotation image by rotating the first rotation image in an opposite direction to a rotation direction of the first rotation image. The simulation is performed by using the vectorized first kernel, the first rotation image, and the second rotation image.

### BRIEF DESCRIPTION OF THE DRAWINGS

Embodiments will be more clearly understood from the following detailed description taken in conjunction with the accompanying drawings in which:

FIG. 1 is a schematic flowchart illustrating a process of an optical proximity correction (OPC) method according to an embodiment;

FIG. 2 is a schematic flowchart illustrating a process of an OPC method according to an embodiment;

FIG. 3 is a schematic flowchart illustrating the process of the OPC method of FIG. 2;

FIGS. 4A and 4B are diagrams for explaining a dot product of a kernel and an image in an OPC method according to an embodiment;

FIG. 5 is a diagram for explaining a dot product of a kernel and an image in an OPC method according to an embodiment;

FIG. 6 is a schematic flowchart illustrating part of a process of an OPC method according to an embodiment;

FIG. 7 is a diagram for explaining symmetry in an OPC method according to an embodiment;

FIG. 8 is a graph illustrating a comparison of errors between an OPC method according to an embodiment and a comparative example;

FIG. 9 is a graph illustrating a comparison of errors between an OPC method according to an embodiment and a comparative example;

FIG. 10 is a schematic flowchart illustrating a process of a method of manufacturing a mask by using an OPC method according to an embodiment;

FIGS. 11A and 11B are schematic flowcharts illustrating a process of an OPC method according to an embodiment; and

FIGS. 12 and 13 are flowcharts illustrating a method of manufacturing a semiconductor device according to an embodiment.

### DETAILED DESCRIPTION OF THE EMBODIMENTS

Hereinafter, embodiments are described in detail with reference to the accompanying drawings. In the drawing and description, like reference numerals and/or letters have been used to identify like features and elements, and redundant descriptions thereof may be omitted.

In the following embodiments, terms such as first and second are not used in a limited sense, but used for the purpose of distinguishing one component or steps, etc., from another. A term that is referenced with a particular ordinal number (e.g., “first”) in a particular claim may be described elsewhere with a different ordinal number (e.g., “second”) in the specification or another claim.

In the following embodiments, singular expressions include plural expressions unless the context clearly indicates otherwise, and the description of a single item that is provided in plural (for example, in the drawings) should be understood to be applicable to the remaining plurality of items.

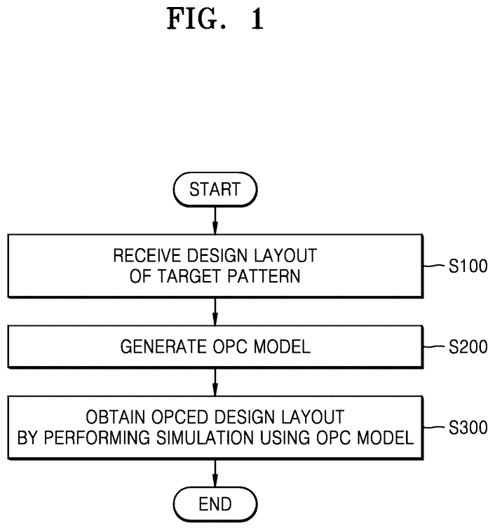

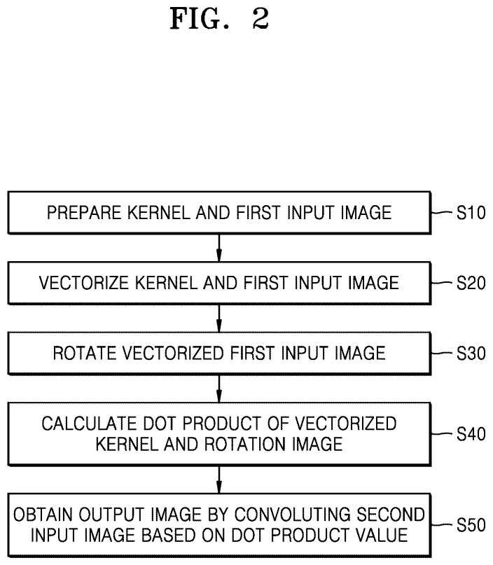

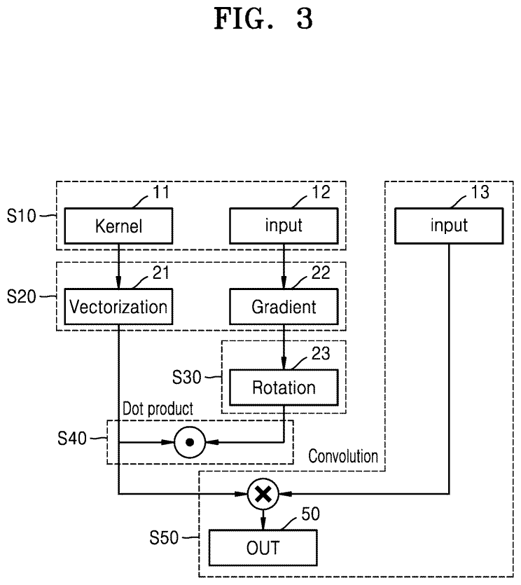

FIGS. 1 and 2 are schematic flowcharts illustrating a process of an optical proximity correction (OPC) method according to an embodiment. FIG. 3 is a schematic flowchart illustrating the process of the OPC method of FIG. 2.

Referring to FIG. 1, the OPC method according to an embodiment may include receiving a design layout of a target pattern to be formed on a substrate (S100). Here, the target pattern may refer to a pattern that is intended to be formed on a silicon (Si) substrate such as a wafer. For example, a plurality of patterns may be formed on a substrate by transferring a plurality of patterns of a mask through an exposure process.

The design layout of a target pattern may be a target design layout. For example, the target design layout may be the most ideal design layout and include information on patterns that is desired to be formed on the substrate. The target design layout may be a layout of a plurality of patterns in correspondence to the target patterns.

Because the pattern on a mask may be projected and transferred in reduced size to a substrate, the size and/or shape of the pattern on the mask may unintentionally become larger, smaller, or otherwise distorted. This is due to the nature of an exposure process. For example, the shape of a pattern on a wafer, which is obtained by an exposure process or lithography process, may be different from the shape of a pattern on a mask used in the exposure process or lithography process. In some cases, the shape of a mask design layout of the pattern on the mask may be substantially the same as the shape of an initial design layout of the pattern on the wafer, but this does not always happen.

In general, a design layout may have the shape of a right-angled design layout. The shape of a right-angled design layout may refer to a shape in which edges include only straight lines. For example, a design layout may have a shape of a combination of a rectangle elongated in a horizontal direction and a rectangle elongated in a vertical direction. However, the shape of a design layout is not limited to the shape of a right-angled design layout.

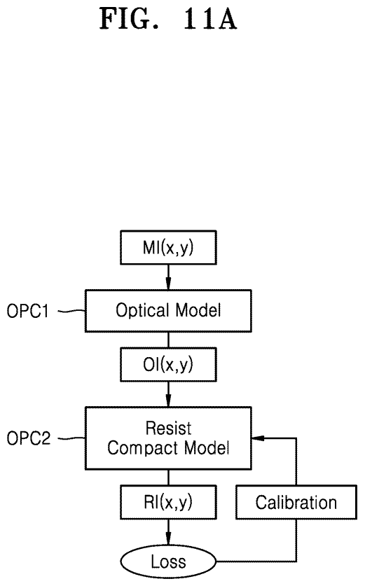

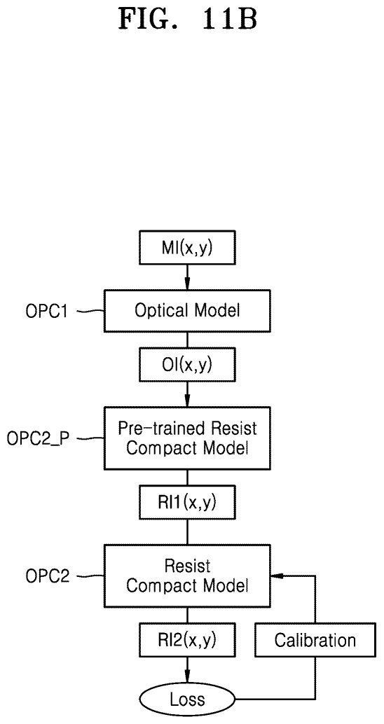

Thereafter, an OPC model may be generated (S200). Generating the optical OPC model may include generating a first OPC model OPC1 (see FIG. 11A) reflecting an optical phenomenon in the exposure process and generating a second OPC model OPC2 (see FIG. 11B) reflecting a physical characteristic of a photoresist (PR). The first OPC model may be understood as an optical OPC model. The second OPC model may be understood as an OPC model with respect to a PR.

With the miniaturization of patterns, an optical proximity effect (OPE) may occur during an exposure process because of an influence between adjacent patterns. The OPC method may be a method for suppressing the occurrence of the OPE by correcting (or modifying) the design layout of a pattern on a mask. For example, the size and the shape of a pattern formed in a wafer may be changed according to the density/arrangement of a pattern on a mask due to an OPE. The OPC method may be used to correct the change. Although various methods may be used to perform OPC, correction using an OPC model may be mainly performed.

The OPC method may include not only modifying the layout (e.g., size and/or shape) of a pattern but also adding sub-lithographic features called serifs on corners of a pattern or adding sub-resolution assist features (SRAFs), such as scattering bars. Here, serifs are usually rectangular features on each corner of a pattern and may be used to sharpen the corners of the pattern or compensate for a distortion factor caused by the intersection of patterns. SRAF is an auxiliary feature introduced to solve an OPC deviation caused by the density difference in the pattern, is formed in a smaller size than the resolution of exposure equipment, and is not transferred to a resist layer.

The OPC method according to the invention may include preparing basic data for OPC. The basic data may include a target design layout for the target pattern, physical and optical parameters of the photolithography process (e.g., the wavelength of the light, numerical aperture (NA) of the lens, resolution limits, the specific features of the mask (e.g., materials and mask geometry such as dimensions of the elements in the mask) and so on). For example, the basic data may include data about shapes of patterns of a sample, positions of the patterns and so on. The basic data may further include measurement information, such as type of apparatus for measurement, type of measurement positions (e.g., spaces or lines of the patterns), and basic measurement values (e.g., target range of feature sizes (Critical Dimensions (CDs)). The basic data may also include information, such as a thickness, a refractive index, and a dielectric constant of a PR, and a source map with respect to a shape of an illumination system. The basic data is not limited to those described above.

After the basic data is prepared, the first OPC model, i.e., an optical OPC model, may be generated. The OPC model may be a simulation (or mathematical) tool used to predict, for example, how light behaves during the photolithography process. The OPC model may include a set of modeling components (such as kernels, images, etc.) used in the OPC, and may also include the operation procedure of the method using the modeling components. The generation of the optical OPC model may take into account process variations. For example, the generation of the optical OPC model may include optimization process for both a defocus stand (DS) position and a best focus (BF) position in an exposure process.

The generation of the optical OPC model may consider diffraction of light or an optical state of exposure equipment. However, the generation of the optical OPC model is not limited to those described above. The generation of the optical OPC model may include considering various contents related to optical phenomena in the exposure process. For example, regarding the generation of an OPC model, an optical mask image, i.e., a near-field image of a mask, may be calculated first, considering the effect of mask topography. Although the near-field image of a mask may be calculated using a rigorous simulation method, such as a rigorous coupled-wave analysis (RCWA) simulation or a finite difference time domain (FDTD) simulation, an edge filter may be usually used for fast calculation of a mask near-field image.

After the first OPC model is generated, the second OPC model may be generated. The generation of the second OPC model may include an optimization process that takes into account a threshold value of the PR. Here, the threshold value of the PR may refer to a threshold value at which a chemical change (e.g., chemical reaction materially changing the PR) occurs during an exposure process. For example, the threshold value may be given as an intensity of exposure light. The generation of the second OPC model may also include selecting appropriate kernel functions from among a plurality of resist kernel functions and combining the selected kernel functions. Here, a kernel function may be a basis function used in non-parametric estimation techniques and may be used to simulate the characteristics of a resist image in the OPC model. However, the invention is not limited thereto. For example, kernel functions may also be used in parametric methods.

After the OPC model is generated, an optical proximity corrected (OPCed) design layout may be obtained by performing a simulation using the OPC model (S300). Because the OPC model includes the first OPC model and the second OPC model, the simulation using the OPC model may include a simulation using the first OPC model and a simulation using the second OPC model. An optic image (or an aerial image, or a first processed image) may be generated through the simulation using the first OPC model. A resist image (or a second processed image) may be generated through the simulation using the second OPC model. The optic image of the first OPC model and the physical characteristics of a PR may be input to the second OPC model. The physical characteristics of the PR may include characteristics based on components of the PR, developer, and the shape, the slope, and the thickness of a PR pattern.

A contour may be extracted from a simulation image (corresponding to a predicted pattern resulting from OPC). In some embodiments, the OPC model may also be used to extract the contour. In some embodiments, the contour (e.g., a two dimensional image) may then be converted into a topological image (e.g., a three dimensional pattern image). The contour and/or the topological image may be compared to the target design layout. When the contour is desirably similar to the target pattern, a design layout corresponding to the contour may be obtained as an OPCed design layout.

In some embodiments, the comparison process may be repeated until the contour and/or the topological image are desirably similar to the target design layout. Consequently, the OPC method may correspond to a series of processes of making the contour extracted through a series of simulations using the OPC model as similar as possible to the shape of the target pattern. The process of simulation and comparison using the OPC model does not end at once but may be repeated tens to hundreds of times, and the OPC model may be updated repeatedly (e.g., trained) to ensure that the shape and/or size of the OPCed pattern closely match the shape and/or size of the mask pattern to be formed on the wafer as closely as possible.

More specifically, when a target design layout is initially received, the design layout may be divided into multiple segments and then input to the OPC model. A segment may be called a fragment and may refer to a straight line corresponding to an edge of a design layout or data corresponding to the straight line. For example, a fragment may represent or include a plurality of straight lines corresponding to edges of a plurality of patterns in the target design layout, and may describe linear paths or a set of coordinates that together form a portion of the overall design.

Thereafter, with respect to one of the segments, a simulation image may be generated through a simulation using the OPC model and a contour corresponding to the target pattern may be extracted from the simulation image. Subsequently, the target pattern may be compared with the contour and an edge placement error (EPE) may be calculated. Here, the EPE may indicate a difference between an edge of the target pattern and a simulation contour. The EPE is usually calculated at each set of evaluation points. Thereafter, the positions of the segments may be changed. For example, with respect to each of the other segments, a contour may be extracted through a simulation using the OPC model and an EPE may be calculated.

This process may be repeated until the EPE falls within a set range or until the number of repetitions reaches a set number. After termination of repetition, the final design layout may correspond to the OPCed design layout. For example, the final simulation image may be the OPCed design layout as a result of the operation S300 of obtaining the OPC design layout.

Referring to FIG. 2, the OPC method according to an embodiment may include preparing a kernel and a first input image (S10), vectorizing the kernel and the first input image (S20), rotating the first input image (S30), calculating a dot product of the vectorized kernel and a rotation image (S40), and obtaining an output image by convoluting a second input image based on a dot product value (S50). Here, operations S10 to S40 may be included in operation S200 of generating the OPC model of FIG. 1 (specifically, generating the second OPC model), and operation S50 may be understood as being included in operation S200 of generating the OPC model of FIG. 1 or operation S300 of obtaining the OPC design layout by performing a simulation using the OPC model. In some embodiments, the operations S10 to S50 may be at least part of a simulation process included in the OPC model.

First, the kernel and the first input image are prepared (S10). Referring to FIGS. 2 and 3 together, operation S10 of preparing the kernel and the first input image may prepare a first kernel 11 and a first input image 12. The first input image 12 may be prepared by a process using the design layout of the target pattern. The first input image 12 may be an output of a process (or a simulation) using a model, which may include a kernel. For example, the first input image 12 may be an optic image output from the above-described first OPC model or an output image with respect to a certain kernel. For example, the first input image 12 may be an image obtained by using a part of or a whole of the process described with reference to FIGS. 1 to 3. For example, the first input image 12 may be the first processed image, which is previously generated through the simulation using the first OPC model (reflecting an optical phenomenon in an exposure process) as described with reference to FIG. 1 in a previous simulation in the series of simulations. In an embodiment, the first kernel 11 may be a Gaussian kernel, but the embodiment is not limited thereto and the first kernel 11 may be at least one of various types of kernels.

Thereafter, the kernel and the first input image are vectorized (S20). In operation S20 of vectorizing the kernel and the first input image, the first kernel 11 and the first input image 12 may be vectorized to have directionality. Accordingly, a vectorized first kernel 21 and a vectorized first input image 22 may be obtained.

In an embodiment, the vectorized first kernel 21 may be obtained by multiplying the first kernel 21 by a direction vector (unit vector) as shown in Equation 1.

$$f ( x , y ) \to f ( x , y ) \hat{r} = f ( x , y ) ( cos θ \hat{x} + sin θ \hat{y} ) \qquad ( Equation 1 )$$

In Equation 1,

$$cos θ = \frac{x}{\sqrt{{x}^{2} + {y}^{2}}} ,$$

f(x, y) indicates the first kernel 11, and f(x, y)\hat{r} indicates the vectorized first kernel 21.

In an embodiment, the vectorized first input image 22 may be calculated based on a gradient vector of the first input image 12 as shown in Equation 2.

$$I ( x , y ) \to ∇ I ( x , y ) = \frac{\partial I}{\partial x} \hat{x} + \frac{\partial I}{\partial y} \hat{y} \qquad ( Equation 2 )$$

In Equation 2, I(x, y) indicates the first input image 12, ∇I(x, y) indicates the vectorized first input image 22, and

$$\frac{\partial I}{\partial x} , \frac{\partial I}{\partial y}$$

indicates a gradient.

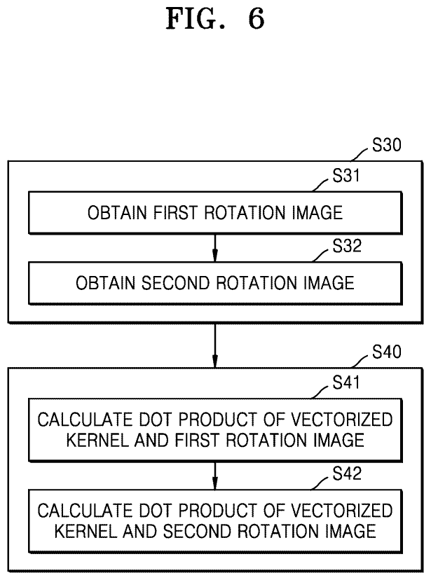

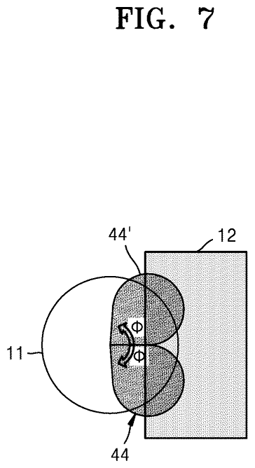

The vectorized first input image 22 may be rotated (S30). A rotation image 23 may be obtained through operation S30 of rotating the vectorized first input image 22. For example, the rotation image 23 may include a first rotation image obtained by rotating the vectorized first input image 22 in a first direction and/or a second rotation image obtained by rotating the vectorized first input image 22 in a second direction. A detailed description thereof will be described below with reference to FIGS. 6 and 7. In an embodiment, the rotation image 23 may be expressed as shown in Equation 3.

$${R}_{ϕ} ( ∇ I ( {x}^{′} , {y}^{′} ) ) = ( \frac{\partial I}{\partial x} cos ϕ - \frac{\partial I}{\partial y} sin ϕ ) \hat{x} + ( \frac{\partial I}{\partial x} sin ϕ + \frac{\partial I}{\partial y} cos ϕ ) \hat{y} \qquad ( Equation 3 )$$

In Equation 3, R_{φ}(∇I(x, y)) indicates the rotation image 23 and φ indicates a rotation angle.

Next, the dot product of the vectorized first kernel 21 and the rotation image 23 may be calculated (S40). A second kernel reflecting the influence of a side surface of a PR may be extracted by calculating the dot product of the vectorized first kernel 21 and the rotation image 23. For example, the second kernel may be a kernel included in a second OPC model (which corresponds to the second OPC model reflecting an influence of a side surface of a PR in the exposure process as described with reference to FIG. 1) to be used in a next simulation in the series of simulations. In an embodiment, the dot product of the vectorized first kernel 21 and the rotation image 23 may be expressed as shown in Equation 4.

$$F ( x , y ; {x}^{′} , {y}^{′} ) = f ( x , y ) \hat{r} \cdot {R}_{ϕ} ( ∇ I ( {x}^{′} , {y}^{′} ) ) = f ( x , y ) \{ ( \frac{\partial I}{\partial x} cos ϕ - \frac{\partial I}{\partial y} sin ϕ ) cos θ + ( \frac{\partial I}{\partial x} sin ϕ + \frac{\partial I}{\partial y} cos ϕ ) sin θ \} \qquad ( Equation 4 )$$

In Equation 4, F(x, y; x′, y′) indicates the second kernel, f(x, y)\hat{r} indicates the vectorized first kernel 21, and R_{φ}(∇I(x, y)) indicates the rotation image 23.

Thereafter, an output image 50 may be obtained by convoluting the second input image based on the dot product value (S50). For example, the output image 50 may be obtained by convoluting the second kernel with the second input image 13. The second input image 13 may be the same as the first input image 12. Alternatively, when the first input image 12 is the output image obtained by a process using the certain kernel as described above, the first input image 12 and the second input image 13 may be different from each other. In an embodiment, the convolution of the second kernel and the second input image 13 may be expressed as shown in Equation 5.

$$O ( {x}^{′} , {y}^{′} ) = \int dxdyI ( {x}^{′} - x , {y}^{′} - y ) F ( x , y ; {x}^{′} , {y}^{′} ) = \int dxdyI ( {x}^{′} - x , {y}^{′} - y ) f ( x , y ) \hat{r} \cdot {R}_{ϕ} ( ∇ I ( {x}^{′} , {y}^{′} ) ) \qquad ( Equation 5 )$$

In Equation 5, O(x′, y′) indicates the output image 50, I(x′−x, y′−y) indicates the second input image 13, and F(x, y; x′, y′) indicates the second kernel.

The second OPC model including the second kernel, which predicts the reaction of a PR from exposure to development in a photolithography process, is important to determine the performance of the OPC. The reaction of the PR is a series of complex physicochemical reactions, and a model for explaining this may be a linear combination of values convoluted with an image such as a nonlinear kernel reflecting the physicochemical reaction of the PR. Leaning of the second OPC model may be performed by learning parameters (e.g., standard deviation in the case of a Gaussian kernel) of kernels constituting the second OPC model and a constant value upon a linear combination (by using a test pattern) such that errors may be minimized.

For example, the training of the second OPC model may be performed by adjusting the parameters of the kernels constituting the second OPC model. To enhance the accuracy of the output of the simulation, the training process may include iterative comparisons between the simulated results generated by the model and the test samples obtained by performing a real fabrication process. For example, the training of the second OPC model may be trained using deep learning. The general kernels in this regard have difficulty in reflecting all the physicochemical reactions of a PR. In particular, models with complex or highly dense patterns may have bad consistency due to the great influence of patterns around the test.

The OPC method according to various embodiments may train a model by vectorizing an input image, rotating the image in a direction of desired side surface, calculating a dot product of a vectorized kernel and the image, and obtaining a kernel (the second kernel). The kernel (the second kernel) according to the inventive concept may reflect the influence of the side surfaces as well as the influence of front and rear surfaces of a measurement direction, and thus the consistency of the OPC model (the second OPC model) may be improved. For example, the training of the OPC model may be trained using deep learning

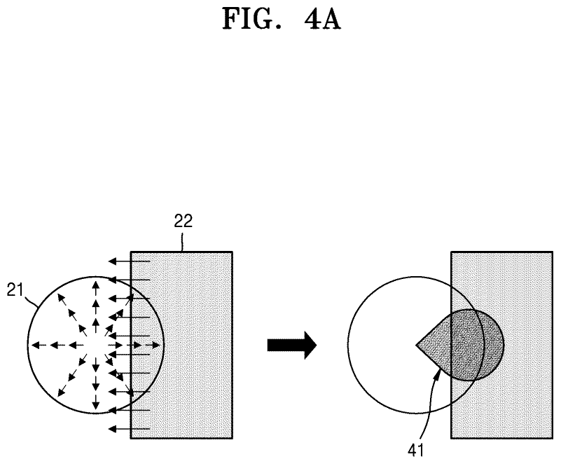

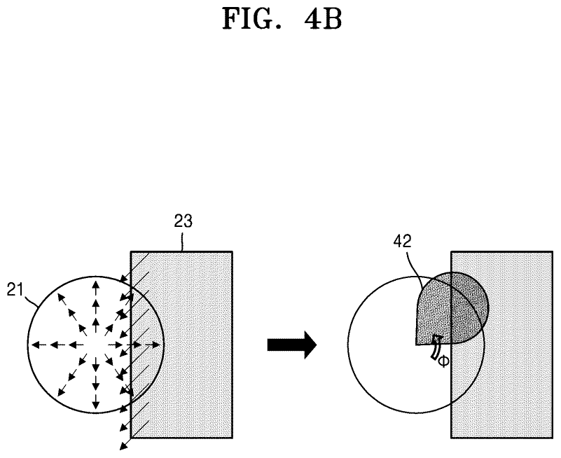

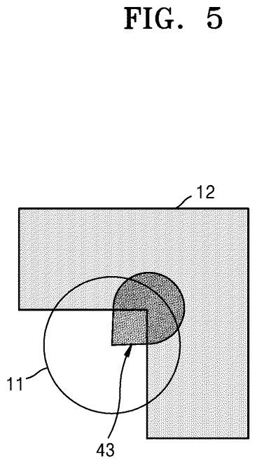

FIGS. 4A, 4B, and 5 are diagrams for explaining a dot product of a kernel and an image in an OPC method according to an embodiment.

In the dot product between a vectorized kernel and a vectorized image, the large dot product value may be obtained in a specific region of the image, where the kernel and the image vector point in the same or opposite directions. When the image is rotated, the direction of its vector changes. As a result, the region of the image that produces a large dot product value may also change.

FIG. 4A shows a region 41 having a large dot product value between the vectorized first kernel 21 and the vectorized first input image 22, and FIG. 4B shows a region 42 having a large dot product value between the vectorized first kernel 21 and the rotation image 23. In FIGS. 4A and 4B, arrows displayed on the kernel and the image indicate directions of vectorized kernel and image (e.g., the directions defined by the vectors of the kernel and image).

Considering that the magnitude of the dot product value is the largest when directions of two vectors are the same or opposite, when the dot product of the kernel and the image is calculated by rotating the image, the regions 41 and 42 having the large inner values may view a direction in which the image has rotated, as shown in FIGS. 4A and 4B. For example, the regions 41 and 42 may represent areas having a large dot product value. The region 41 may correspond to the case when the image is not rotated (e.g., the image has the same orientation as the received design layout), while the region 42 may correspond to the case when the image is rotated (e.g., the image has a different orientation from the received design layout).

Referring to FIG. 5, when the first input image 12 has a side pattern, a second kernel (the dot product value) used in the OPC method according to various embodiments may train an OPC model in consideration of the influence of the side surface, unlike the existing kernel that has a large dependence only on a front region. As shown in FIG. 5, by rotating the image to change the region of a large dot product value, the influence between adjacent two edges of a pattern may be more accurately considered. For example, the training of the OPC model may be trained using deep learning

FIG. 6 is a schematic flowchart illustrating a part of a process of an OPC method according to an embodiment. FIG. 7 is a plan view for explaining symmetry in an OPC method according to an embodiment.

Referring to FIGS. 6 and 7 together with FIGS. 2 and 3, operation S30 of rotating the vectorized first input image 22 may include obtaining a first rotation image (S31) and obtaining a second rotation image (S32). The second rotation image may be obtained by symmetrizing the first rotation image. For example, the first rotation image may be obtained by rotating the vectorized first input image 22 in a first direction, and the second rotation image may be obtained by rotating the vectorized first input image 22 in a second direction opposite to the first direction. In an embodiment, each of the first direction and the second direction may be a clockwise direction or a counterclockwise direction.

In an embodiment, a rotation angle of the first rotation image and a rotation angle of the second rotation image may be the same. That is, the second rotation image may be obtained by rotating the vectorized first input image 22 in the opposite direction to the rotation direction of the first rotation image and at the same angle as the rotation angle of the first rotation image.

In some embodiments, the first and second images may be obtained by rotating the input image in a clockwise direction and a counterclockwise direction, respectively. The first and second images may be rotated by the same angle as each other such that the region 44 of a large dot product value (resulting from the clockwise-rotated image) is in symmetry with the region 44′ of a large dot product value (resulting from the counterclockwise-rotated image) with respect to a horizontal line in the plan view of FIG. 7.

Referring to FIGS. 3 and 6, operation S40 of calculating a dot product of a vectorized kernel (e.g., the vectorized first kernel 21) and the rotation image 23 may include calculating a dot product of the vectorized first kernel 21 and the first rotation image (S41), and calculating a dot product of the vectorized first kernel 21 and the second rotation image (S42). Dot product values may be calculated by calculating the dot product of each of the first rotation image and the second rotation image with the vectorized first kernel 21.

Thereafter, as shown in Equation 6 and FIG. 3, the output image may be extracted by convoluting the sum of the dot product values with the second input image 13. For example, a second kernel may be extracted by calculating the dot product of the vectorized first kernel 21 and the first rotation image, a fourth kernel may be extracted by calculating the dot product of the vectorized first kernel 21 and the second rotation image, and then the output image may be extracted by convoluting the sum of the second kernel and the fourth kernel with the second input image 13.

$$O ( {x}^{′} , {y}^{′} ) = \int dxdyI ( {x}^{′} - x , {y}^{′} - y ) \text{} \{ f ( x , y ) \hat{r} \cdot {R}_{ϕ} ( ∇ I ( {x}^{′} , {y}^{′} ) ) + f ( x , y ) \hat{r} \cdot {R}_{- ϕ} ( ∇ I ( {x}^{′} , {y}^{′} ) ) \} \qquad ( Equation 6 )$$

Here, O(x′, y′) indicates the output image, R_{φ}(∇I(x′, y′)) indicates the first rotation image, R_{-φ}(∇I(x′, y′)) indicates the second rotation image, f(x, y)\hat{r} indicates the vectorized first kernel 21, and I(x′−x, y′−y) indicates the second input image 13.

Due to the symmetry of the first rotation image and the second rotation image, the sum of the second kernel and the fourth kernel (or the sum of the dot product values) may have symmetry, and thus the model consistency (or accuracy) may be improved and grid dependence may be removed (or reduced), unlike when a kernel is configured using only an input image rotated and converted in one direction.

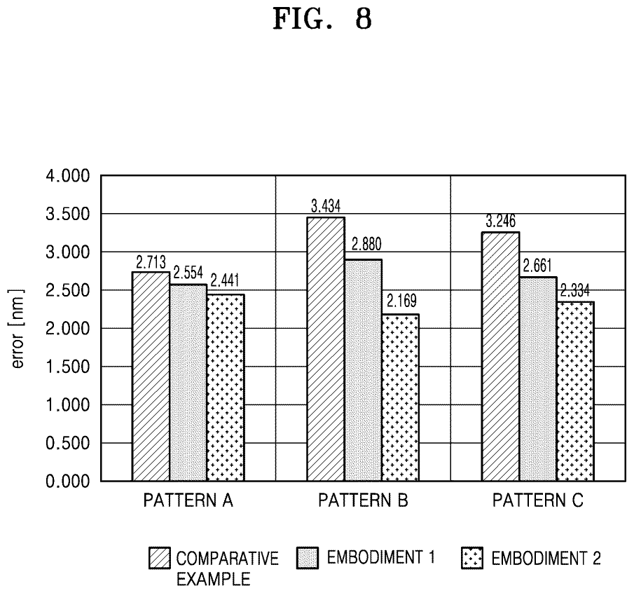

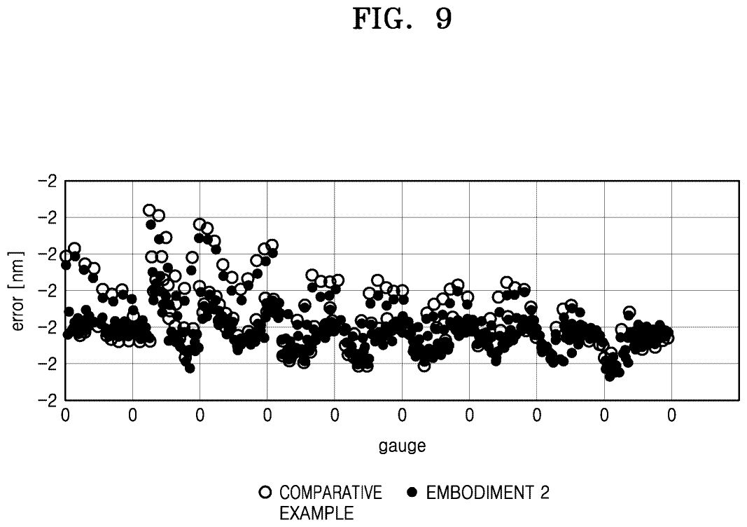

FIGS. 8 and 9 are graphs illustrating a comparison of errors between an OPC method according to an embodiment and a comparative example.

FIG. 8 is the graph illustrating differences in average errors in OPC models of embodiments 1 and 2 and an OPC model of the comparative example when learning patterns A, B, and C. The comparative example relates to the model generated using only an optic image and Gaussian kernels, and embodiment 1 relates to the model generated by adding the sum of the above-described second kernel and fourth kernel (the sum of values obtained by calculating the dot product of each of a first rotation image and a second rotation image and a vectorized first kernel (a rotation angle is 0 degree)) to the model of the comparative example. Embodiment 2 relates to the model generated by adding the sums of the above-described second kernel and fourth kernel (the sums of values obtained by calculating the dot product of each of the first rotation image and the second rotation image and the vectorized first kernel (rotation angles are 45 degrees, 90 degrees, and 135 degrees) to the model of embodiment 1. Referring to FIG. 8, it may be seen that embodiments 1 and 2 have lower average errors in all of the patterns A, B, and C than in the comparative example.

FIG. 9 is the graph illustrating the errors of the comparative example and embodiment 2 in individual patterns belonging to the pattern B of FIG. 8. Referring to FIG. 9, embodiment 2 shows a narrower distribution of errors than the comparative example. That is, it may be seen that the model consistency of embodiment 2 is higher than that of the comparative example.

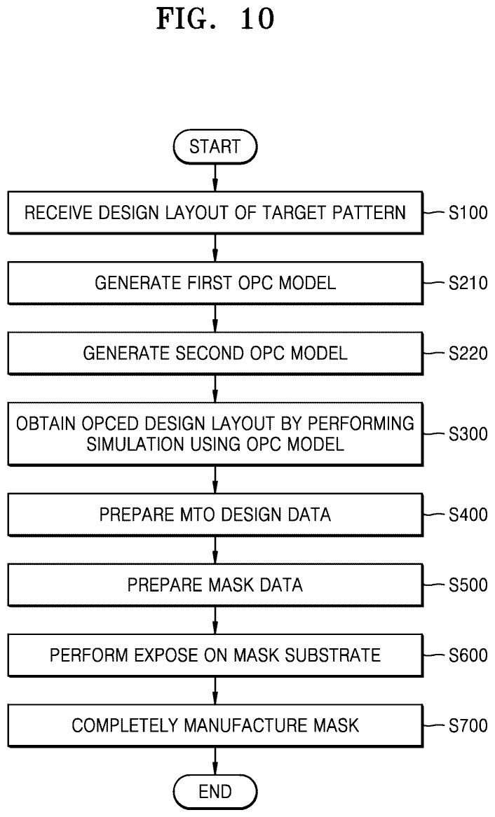

FIG. 10 is a schematic flowchart of a method of manufacturing a mask by using an OPC method according to an embodiment.

According to an embodiment, the method of manufacturing the mask by using the OPC method (hereinafter, referred to as simply as a “mask manufacturing method”) may sequentially perform receiving a design layout of a target pattern (S100) and generating OPCed design layout (S300). Receiving the design layout of the target pattern (S100) and generating the OPCed design layout (S300) may be the same as receiving a design layout of a target pattern (S100) and generating OPCed design layout (S300) in the OPC method of FIG. 1.

Generating an OPC model (S200, see FIG. 1) may include generating a first OPC model (S210) and generating a second OPC model (S220). As described above with reference to FIG. 1, the first OPC model may be an optical OPC model, and the second OPC model may be an OPC model with respect to a PR.

Operation S210 of generating the second OPC model may include preparing the kernel and the first input image (S10) to calculate the dot product of the vectorized kernel and the rotation image (S40) described with reference to FIG. 2. In addition, operation S30 of rotating the vectorized first input image may include obtaining the first rotation image (S31) and obtaining the second rotation image (S32) described above with reference to FIG. 6, and operation S40 of calculating the dot product of the vectorized kernel and the rotation image may include calculating the dot product of the vectorized kernel and the first rotation image (S41), and calculating the dot product of the vectorized kernel and the second rotation image (S42).

Referring to FIG. 10 together with FIG. 3, operation S210 of generating the second OPC model may include first preparing the first kernel 11 and the first input image 12. Thereafter, the vectorized first kernel 21 and the vectorized first input image 22 may be obtained by vectorizing the first kernel 11 and the first input image 12, respectively. The rotation image 23 may be obtained by rotating the vectorized first input image 22. Next, the dot product of the rotation image 23 and the vectorized first kernel 21 may be calculated. The rotation image may include a first rotation image and a second rotation image having symmetry with each other as described with reference to FIG. 6, and in this case, the dot product of each of the first rotation image and the second rotation image and the vectorized first kernel 21 may be calculated. Accordingly, the second OPC model according to an embodiment may consider the influence of the side surface of a PR.

Referring back to FIG. 10, MTO design data may be delivered to a mask manufacturing team (S400). In general, MTO may refer to sending data about a final design layout obtained through an OPC method to a mask manufacturing team and requesting the manufacture of a mask. Accordingly, in the mask manufacturing method of the present embodiment, the MTO design data may refer to an OPCed design layout obtained through the OPC method or data about the OPCed design layout. The MTO design data may have a graphic data format used electronic design automation (EDA) software. For example, the MTO design data may have a data format such as graphic data system II (GDS2) or open artwork system interchange standard (OASIS).

Thereafter, mask data preparation (MDP) may be performed (S500). The MDP may include i) format conversion called fracturing; ii) augmentation of a bar code for machine reading, a standard mask pattern for inspection, or a job deck; and iii) automatic and manual verifications. Here, the job deck may refer to creation of a text file about a series of instructions including information about the arrangement of multiple mask files, a reference dose, or an exposure speed or method.

The format conversion, i.e., fracturing, may refer to a process of dividing the MTO design data into regions and converting the MTO design data into a format for an electron beam (e-beam) writer. For example, the fracturing may include data manipulation such as scaling, data sizing, rotation of data, or pattern reflection. In the conversion process through the fracturing, data about numerous systematic errors, which may occur in a process of delivering design data to an image on a wafer, may be corrected.

The correction of the data about the systematic errors may be referred to as mask process correction (MPC), which may include critical dimension (CD) adjustment and an operation of increasing pattern arrangement accuracy. Accordingly, the fracturing may contribute to an increase in quality of a mask and may be performed in advance for the MPC. Here, the systematic errors may be caused by distortion occurring during an exposure process, a mask development and etching process, or a wafer imaging process.

The MDP may include MPC. As described above, the MPC is a process of correcting errors, i.e., systematic errors, occurring during an exposure process. Here, the exposure process may be a concept generally including e-beam writing, development, etching, and baking. In addition, data processing may be performed before the exposure process. The data processing may be preprocessing of mask data and include grammar check on the mask data and exposure time prediction.

After the MDP, exposure may be performed on a mask substrate based on the mask data (S600). Here, exposure may refer to, for example, electron (e)-beam writing. For example, the e-beam writing may be performed by a gray writing method using a multi-beam mask writer (MBMW). The e-beam writing may also be performed using a variable shape beam (VSB) writer.

After the MDP, a process of converting the mask data into pixel data may be performed before the exposure process. The pixel data may be directly used for actual exposure and include data about the shape of an object to be exposed and data about a dose allocated to the data about the shape. Here, the data about the shape may include bit-map data, into which shape data corresponding to vector data has been converted through rasterization.

After the exposure process, a series of processes may be performed to completely manufacture the mask (S700). For example, the series of processes may include development, etching, and cleaning. The series of processes for manufacturing the mask may also include measurement, defect inspection, or defect repair. The series of processes for manufacturing the mask may further include pellicle coating. The pellicle coating may refer to a process of attaching a pellicle to a mask after confirming that there are no pollutant particles or chemical stains through final cleaning and inspection so as to protect the surface of the mask from contamination during the shipment and working life of the mask.

The OPC method according to an embodiment may further include obtaining a resist image by applying the second OPC model, calculating a loss value through a loss function with respect to the resist image, and adjusting parameters of the second OPC model based on the loss value.

In an embodiment, obtaining the resist image by applying the second OPC model may include using the optic image calculated through the first OPC model as an input image of the second OPC model.

In an embodiment, obtaining the resist image (or first processed image) by applying the second OPC model may include using a pre-trained resist image (or a pre-trained processed image) calculated by applying a pre-trained OPC model to the optic image (or second processed image) calculated through the first OPC model as the input image of the second OPC model. For example, the second processed image may be used as either the first input image, the second input image, both the first and second input images as a whole, or either of the first and second input images (the first and second input images is images described above with respect to FIGS. 1 to 10). For example, the training of the pre-trained OPC model may be trained using deep learning.

FIGS. 11A and 11B are schematic flowcharts illustrating a process of an OPC method according to an embodiment.

Referring to FIG. 11A, an optic image OI(x, y) may be obtained through the first OPC model OPC1 that receives a design layout MI(x, y) with respect to a target pattern and reflects an optical phenomenon in an exposure process with respect to the design layout MI(x, y). Thereafter, a resist image RI(x, y) may be obtained by using the optic image OI(x, y) as an input value in the second OPC model OPC2 described above with reference to FIG. 10. Next, a loss value may be calculated using a loss function with respect to the resist image RI(x, y). Based on the given loss value, the parameter of the second OPC model OPC2 may be adjusted (updated or calibrated) through a coefficient solver, and the above-described process may be repeated until the loss value sufficiently converges.

Referring to FIG. 11B, the optic image OI(x, y) may be obtained through the first OPC model OPC1 that receives the design layout MI(x, y) with respect to the target pattern and reflects the optical phenomenon in the exposure process with respect to the design layout MI(x, y). Thereafter, unlike the embodiment of FIG. 11A, a first resist image RI1(x, y) may be obtained by applying a pre-trained OPC model OPC2_P. Next, a second resist image RI2(x, y) may be obtained by using the first resist image RI1(x, y) as an input value in the second OPC model OPC2 described above with reference to FIG. 10. With respect to the second resist image RI2(x, y), a loss value may be calculated using a loss function as in FIG. 11A, the parameter of the second OPC model OPC2 may be adjusted (updated or calibrated) through a coefficient solver based on the given loss value, and the above-described process may be repeated until the loss value sufficiently converges.

In the OPC method according to various embodiments, an input module may prepare the kernel and the first input image (S10), a vectorization module may vectorize the kernel and the first input image (S20), and a rotation module may rotate the vectorized first input image (S30). Thereafter, a dot product module may calculate the dot product of the vectorized kernel and the rotation image (S40), and an output module may obtain the output image by convoluting the second input image based on the dot product value (S50).

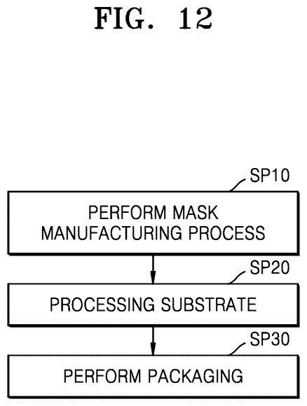

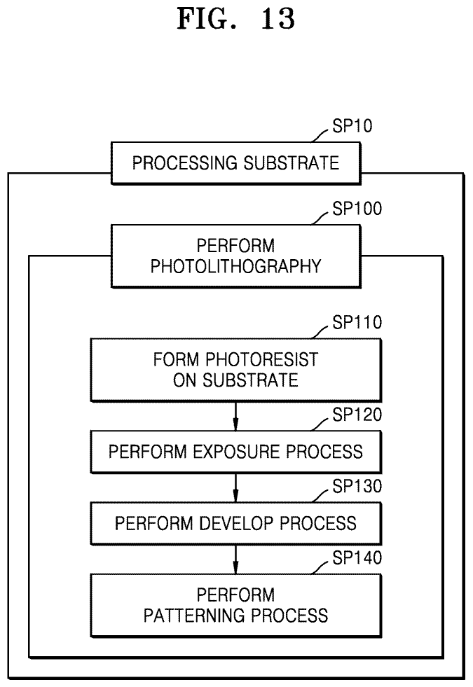

FIGS. 12 and 13 are flowcharts illustrating a method of manufacturing a semiconductor device according to an embodiment.

Referring to FIG. 12, an operation SP10 of a mask manufacturing process may be performed. As an example, the mask manufacturing process may be the process described with reference to FIG. 10. The mask manufacturing process may be performed by using the OPC method according to the embodiments described with reference to FIGS. 1 to 7.

Subsequently, an operation SP20 of processing a substrate (e.g., silicon wafer), thereby manufacturing a plurality of semiconductor chips (devices) are formed on the substrate. In the operation SP30, one or more processes may be performed. For example, an oxidation process, a photolithography process, a deposition process, an ion process, and/or a cleaning process may be performed to form the semiconductor chips.

In an operation S30, the substrate may be singulated (divided) into a plurality of diced chips by, e.g., a sawing process. During the operation S30, one or more of the diced chips may be disposed on a package substrate, and the individual chips may be molded by e.g., a molding compound.

FIG. 13 illustrates a photolithography process SP100 as an example of processes performed in the operation SP10.

Referring to FIG. 13, in an operation SP110, a photoresist layer may be formed on the substrate. In addition, in an operation SP120, an exposure process may be performed using the mask produced by the operation SP10. In an operation SP130, a developing process may be performed to remove portions of the photoresist layer, thereby forming photoresist patterns on the substrate. In an operation SP140, the substrate (or a layer formed on the substrate) may be patterned through, e.g., an etching process. During the etching, the photoresist patterns may be used as an etch mask.

Using the photoresist patterns obtained in the operation SP130 and/or the etched patterns obtained in the operation SP140, the OPC model, which is described with reference to FIGS. 1 to 7, may be updated (or trained). For example, the basic data may include data about shapes of patterns of the photoresist patterns and/or the etched patterns. The basic data may further include measurement information, such as type of apparatus for measurement, type of measurement positions (e.g., spaces or lines of the photoresist patterns and/or the etched patterns), and basic measurement values (e.g., target range of feature sizes (Critical Dimensions (CDs)) of the photoresist patterns and/or the etched patterns obtained in the operations SP140 and SP140. For example, the training of the OPC model may be trained using deep learning.

In some embodiment, the photoresist patterns and/or the etched patterns obtained in the operations SP140 and SP140 may be used to train the second OPC model by adjusting the parameters of the kernels constituting the second OPC model to enhance the accuracy of the output of the simulation. For example, the training of the second OPC model may be trained using deep learning.

While the inventive concept has been particularly shown and described with reference to embodiments thereof, it will be understood that various changes in form and details may be made therein without departing from the spirit and scope of the following claims.

What is claimed is:

1. A method of manufacturing comprising:
receiving a design layout of a target pattern;
generating an optical proximity correction (OPC) model;
obtaining an optical proximity corrected (OPCed) design layout by a simulation using the OPC model; and
forming at least one of a mask and a semiconductor device using the OPCed design layout,
wherein the generating of the OPC model comprises:
obtaining a vectorized first kernel by vectorizing a first kernel,
preparing a first input image by using the design layout of the target pattern,
obtaining a vectorized first input image by vectorizing the first input image,
obtaining a first rotation image by rotating the vectorized first input image in a first direction, and
extracting a second kernel by calculating a dot product of the vectorized first kernel and the first rotation image, and
wherein the simulation is performed by using the second kernel.

2. The method of claim 1,
wherein the generating of the OPC model further comprises preparing a second input image by using the design layout of the target pattern, and
wherein the obtaining of the OPCed design layout includes extracting an output image by convoluting the second kernel and the second input image.

3. The method of claim 2, wherein the second input image is the same as the first input image.

4. The method of claim 2, wherein the first input image is an output image obtained by using a third kernel which is different from the first kernel.

5. The method of claim 1, wherein the obtaining of the vectorized first kernel includes multiplying the first kernel by a direction vector.

6. The method of claim 1, wherein the obtaining of the vectorized first input image is performed by using a gradient vector of the first input image.

7. The method of claim 1, wherein the generating of the OPC model further includes obtaining a second rotation image by rotating the vectorized first input image in a second direction opposite to the first direction.

8. The method of claim 7, wherein a rotation angle of the first rotation image is the same as a rotation angle of the second rotation image.

9. The method of claim 7, wherein the generating of the OPC model further includes extracting a fourth kernel by calculating a dot product of the vectorized first kernel and the second rotation image.

10. The method of claim 9,
wherein the generating of the OPC model further comprises preparing a second input image by using the design layout of the target pattern, and
wherein the obtaining of the OPCed design layout includes extracting an output image by convoluting the second input image and a sum of the second kernel and the fourth kernel.

11. A method of manufacturing comprising:
receiving a design layout of a target pattern;
generating a first OPC model reflecting an optical phenomenon in an exposure process;
generating a second OPC model reflecting an influence of a side surface of a photoresist (PR) in the exposure process;
obtaining an optical proximity corrected (OPCed) design layout by a simulation using an OPC model comprising the first OPC model and the second OPC model; and
forming at least one of a mask and a semiconductor device using the OPCed design layout,
wherein the generating of the second OPC model comprises:
preparing a first input image and a second input image by using the design layout of the target pattern,
obtaining a vectorized first kernel by vectorizing a first kernel,
obtaining a vectorized first input image by vectorizing the first input image,
obtaining a rotation image by rotating the vectorized first input image, and
extracting a second kernel by calculating a dot product of the vectorized first kernel and the rotation image, and
wherein the obtaining of the OPCed design layout includes extracting an output image by convoluting the second kernel and the second input image.

12. The method of claim 11, further comprising:
obtaining a first processed image by applying the second OPC model;
calculating a loss value by using a loss function with respect to the first processed image and the design layout of the target pattern; and
adjusting a parameter of the second OPC model, based on the loss value.

13. The method of claim 12, wherein:
the obtaining of the first processed image by applying the second OPC model includes using a second processed image calculated through the first OPC model, and
the generating of the second OPC model includes using the second processed image as either the first input image, the second input image, both the first and second input images as a whole, or either of the first and second input images.

14. The method of claim 12, wherein:
the obtaining of the first processed image by applying the second OPC model includes using a pre-trained processed image calculated by applying a pre-trained OPC model to a second processed image calculated through the first OPC model, and
the generating of the second OPC model includes using the second processed image as either the first input image, the second input image, both the first and second input images as a whole, or either of the first and second input images.

15. The method of claim 11, wherein the first kernel is a Gaussian kernel.

16. A method of manufacturing comprising:
receiving a design layout of a target pattern;
generating an OPC model;
obtaining an optical proximity corrected (OPCed) design layout by a simulation using the OPC model; and
forming at least one of a mask and a semiconductor device using the OPCed design layout,
wherein the generating of the OPC model comprises:
preparing a first input image by using the design layout of the target pattern,
obtaining a vectorized first kernel by vectorizing a first kernel,
obtaining a vectorized first input image by vectorizing the first input image,
obtaining a first rotation image by rotating the vectorized first input image, and
obtaining a second rotation image by rotating the first rotation image in an opposite direction to a rotation direction of the first rotation image, and
wherein the simulation is performed by using the vectorized first kernel, the first rotation image, and the second rotation image.

17. The method of claim 16, wherein a rotation angle of the second rotation image is the same angle as a rotation angle of the first rotation image.

18. The method of claim 16, wherein the generating of the OPC model further includes calculating dot product values by calculating:
a first dot product of the first rotation image and the vectorized first kernel, and
a second dot product of the second rotation image and the vectorized first kernel.

19. The method of claim 18,
wherein the generating of the OPC model further comprises preparing a second input image by using the design layout of the target pattern, and
wherein the obtaining of the OPCed design layout includes extracting an output image by convoluting the second input image and a sum of values of the first and second dot product.

20. The method of claim 19, wherein the first input image:
is the same as the second input image, or
is an output image obtained by using a second kernel different from the first kernel.
